(19) United States
(12) Patent Application Publication
(10) Pub. No.: US 2009/0213561 A1
(43) Pub. Date: Aug. 27, 2009

(54) ELECTRONIC DEVICE

(75) Inventors: Xiaoyu Mi, Kawasaki (JP); Takeo Takahashi, Yokohama (JP); Satoshi Ueda, Kawasaki (JP); Tatsuya Kakehashi, Yokohama (JP); Hidehiko Ishiguro, Yokohama (JP); Shinya Yamamoto, Yokohama (JP)

Correspondence Address: ARENT FOX LLP, 1050 CONNECTICUT AVENUE, N.W., SUITE 400, WASHINGTON, DC, 20036, US

(73) Assignees: FUJITSU MEDIA DEVICES LIMITED, Yokohama-shi (JP); FUJITSU LIMITED, Kawasaki (JP)

(21) Appl. No.: 12/391,843

(22) Filed: Feb. 24, 2009

(30) Foreign Application Priority Data
Feb. 26, 2008 (JP) 2008-045173

(51) Int. Cl. H05K 7/00

(52) U.S. Cl. 361/782

(57) ABSTRACT

An electronic device includes an insulative substrate, a spiral inductor formed by an interconnection layer provided on a first surface of the insulative layer, a first chip that is mounted on a second surface of the insulative layer opposite to the first surface and is electrically connected to a passive circuit including the spiral inductor, the first chip having an electrically conductive substrate, and a first protrusion that is provided on one of the first and second surface of the insulative substrate and protrudes therefrom, the first protrusion being electrically connected to one of the passive circuit and the first chip to an external circuit.

### CROSS-REFERENCE TO RELATED APPLICATION

This application is based upon and claims the benefit of priority of the prior Japanese Patent Application No. 2008-045173, filed on Feb. 26, 2008, the entire contents of which are incorporated herein by reference.

### FIELD

The present embodiments described herein relate to an electronic device having an insulative substrate on which a spiral inductor and a chip are mounted.

### BACKGROUND

There has been considerable activity in speeding up, downsizing, multi-functioning and power saving in information processing devices such as mobile communication terminals and personal computers. In order to achieve these attempts, electronic devices are required to have higher integration and higher performance. This requirement may be met by a multi-chip module in which multiple elements such as a semiconductor chip and an inductor are housed in a single module (see Japanese Laid-Open Patent Publication Nos. 10-294421 (Document 1) and 2000-36657 (Document 2).

An electronic device having an insulative substrate on which a spiral inductor is formed is described in Japanese Laid-Open Patent Publication Nos. 2006-157738 (Document 3) and 2007-67236 (Document 4).

Preferably, an electronic device in which a semiconductor chip and an inductor are integrated has an arrangement in which a spiral inductor is formed by an interconnection layer formed on an insulative substrate as described in Documents 3 and 4 in order to miniaturize the inductor and improve the Q value thereof It is to be noted that the spiral inductor formed by the interconnection layer generates a strong magnetic field. The semiconductor chip uses an electrically conductive silicon substrate. When the semiconductor chip is placed in the strong magnetic field formed by the spiral inductor, an eddy current is generated in the semiconductor chip and may cause a circuit formed in the semiconductor chip to malfunction.

### SUMMARY

According to an aspect of the present invention, there is provided an electronic device includes an insulative substrate, a spiral inductor formed by an interconnection layer provided on a first surface of the insulative layer, a first chip that is mounted on a second surface of the insulative layer opposite to the first surface and is electrically connected to a passive circuit including the spiral inductor, the first chip having an electrically conductive substrate, and a first protrusion that is provided on one of the first and second surface of the insulative substrate and protrudes therefrom, the first protrusion being electrically connected to one of the passive circuit and the first chip to an external circuit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view of an electronic device in accordance with an aspect of the present invention;

FIGS. 2A through 2C illustrate a first embodiment;

FIG. 3 is a perspective view of an inductor;

FIGS. 4A through 4C illustrate a second embodiment;

FIGS. 5A through 5C illustrate a third embodiment;

FIGS. 6A through 6C illustrate a fourth embodiment;

FIGS. 7A through 7C illustrate a fifth embodiment;

FIGS. 8A through 8C illustrate a sixth embodiment;

FIGS. 9A through 9C illustrate a seventh embodiment;

FIGS. 10A through 10C illustrate an eighth embodiment;

FIGS. 11A through 11C illustrate a ninth embodiment;

FIGS. 12A through 12C illustrate a tenth embodiment;

FIGS. 13A through 13C illustrate an eleventh embodiment;

FIGS. 14A through 14C illustrate a twelfth embodiment;

FIGS. 15A through 15C illustrate a thirteenth embodiment;

FIGS. 16A through 16C illustrate a fourteenth embodiment;

FIGS. 17A through 17C illustrate a fifteenth embodiment;

FIGS. 18A through 18C illustrate a sixteenth embodiment (part 1);

FIGS. 19A through 19C illustrate the sixteenth embodiment (part 2);

FIGS. 20A through 20D illustrate a seventeenth embodiment (part 1);

FIGS. 21A and 21B illustrate the seventeenth embodiment (part 2);

FIGS. 22A through 22D illustrate the seventeenth embodiment (part 3);

FIGS. 23A and 23B illustrate the seventeenth embodiment (part 4); and

FIGS. 24A and 24B illustrate the seventeenth embodiment (part 5).

### DESCRIPTION OF EMBODIMENTS

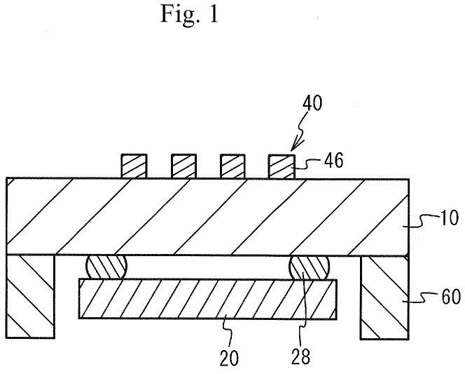

First, a description will be given of an aspect of the present invention. FIG. 1 is a cross-sectional view of an electronic device in accordance with an aspect of the present invention. An interconnection line made of a metal such as copper (Cu) or gold (Au) is formed on the upper surface of an insulative substrate 10, which may be made of HTCC (High Temperature Co-fired Ceramics) or LTCC (Low Temperature Co-fired Ceramics). A spiral inductor 40 is formed by the interconnection layer. The spiral inductor 40 may be formed on the upper surface of the insulative substrate 10 directly or indirectly via an insulative film. A first chip 20 having an electrically conductive substrate is mounted on a lower surface of the insulative substrate 10. The first chip 20 may be attached to the insulative substrate 10 in flip-chip mounting or face-up mounting. The first chip 20 is electrically connected to the spiral inductor 40 via an interconnection line within the insulative substrate 10 and another member (which may, for example, be a second chip, a third chip or a surface-mounting component employed in embodiments described hereinafter). The first chip 20 may be connected to a passive circuit that includes the spiral inductor 40. The passive circuit may be a circuit formed by only the spiral inductor 40 or a circuit including at least one of a capacitor, a resistor and a line in addition to the spiral inductor 40. The passive circuit may include multiple inductors or multiple capacitors.

A first protrusion 60 is provided on the lower surface of the insulative substrate 10 and protrudes from the insulative substrate 10. The first protrusion 60 is a member for electrically connecting the passive circuit including the spiral inductor 40 or the first chip 20 to an external mount board or the like. The structure illustrated in FIG. 1 may be varied so that the first protrusion 60 is attached to the upper surface of the insulative substrate 10. The passive circuit or the first chip 20 may be electrically connected to another member (which may, for example, be a second chip, a third chip or a surface-mounting component employed in embodiments described later).

In accordance with the structure illustrated in FIG. 1, the first chip 20 is mounted so as to overlap the spiral inductor 40, whereby the electronic device can be downsized. The spiral inductor 40 is formed on the upper surface of the insulative substrate 10 and the electrically conductive first chip 20 is mounted on the lower surface of the insulative substrate 10. It is thus possible to increase the distance between the spiral inductor 40 and the first chip 20 and to reduce the magnetic flux density resulting from the spiral inductor 40 on the first chip 20. It is thus possible to restrain malfunction of the first chip 20. It is further possible to reduce loss caused by the eddy current flowing in the first chip 20 due to the spiral inductor 40. Furthermore, it is possible to efficiently mount the spiral inductor 40 and the first chip 20.

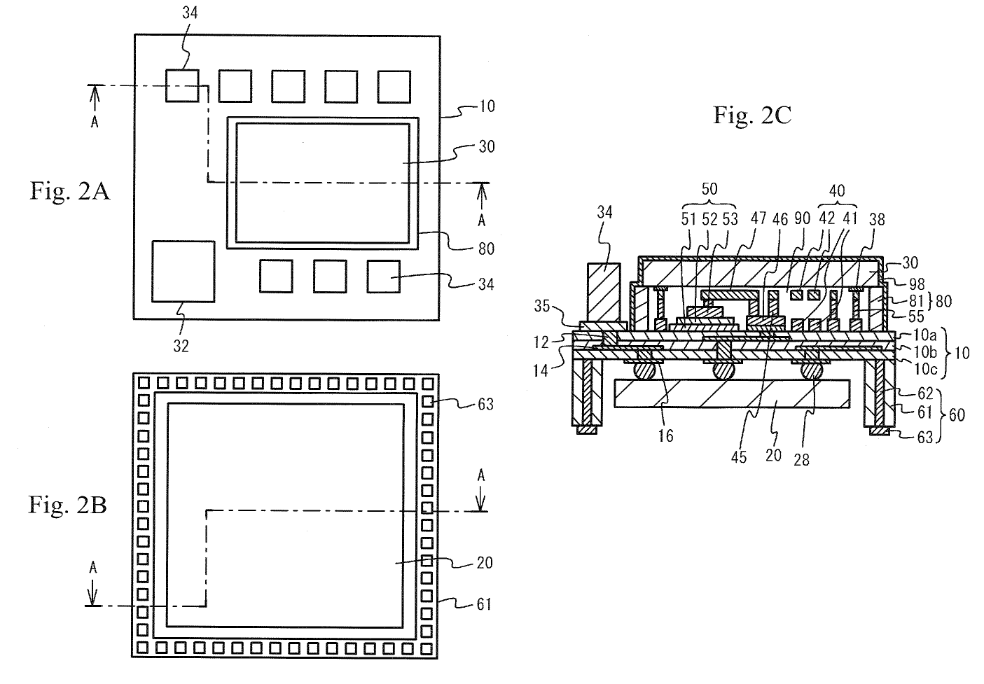

FIG. 2A is a plan view of an electronic device in accordance with a first embodiment, FIG. 2B is a bottom view thereof, and FIG. 2C is a cross-sectional view taken along a line A-A depicted in FIGS. 2A and 2B. The insulative substrate 10 is a ceramic multilayer substrate composed of, for example, three layers 10a, 10b and 10c. Through electrodes 12, inner interconnections 14 and pad electrodes 16 are provided to the insulative substrate 10. The spiral inductor 40 and an MIM (Metal Insulator Metal) capacitor 50 are formed on the upper surface of the insulative substrate 10. The spiral inductor 40 and the capacitor 50 form a passive circuit. A second protrusion 80 is provided on the upper surface of the insulative substrate 10 so as to surround the spiral inductor 40 and the capacitor 50. The second protrusion 80 has a cavity wall formed by an insulative member such as ceramics. A second chip 30 is mounted on the second protrusion 80. A seal member 98 covers the second protrusion 80 and the second chip 30. Thus, a cavity 90 defined by the second protrusion 80 and the second chip 30 can be hermitically sealed. The seal member 98 may be an insulative material having insulative resin or glass as a major component or a solder material including an electrically conductive substance.

The spiral inductor 40 includes a first coil 41, a second coil 42, and a connecting portion 45 for connecting the first coil 41 and the second coil 42. The capacitor 50 is composed of a lower electrode 51, a dielectric layer 52 and an upper electrode 53. The spiral inductor 40 and the capacitor 50 are connected by interconnections 46 and 47. A connecting portion 55 electrically connects the second chip 30 and the inductor or the first chip 20.

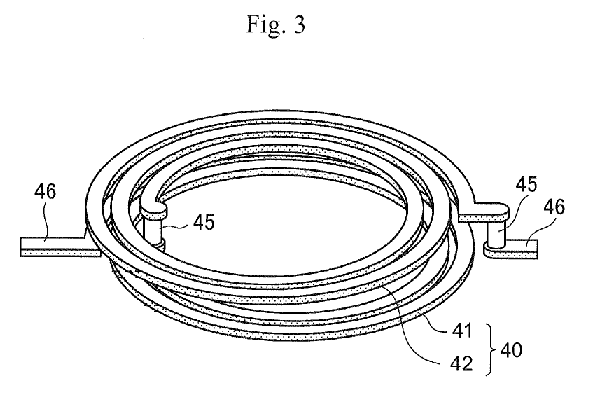

FIG. 3 is a perspective view of the spiral inductor 40. As depicted, the spiral inductor 40 has a first coil 41 formed on the insulative substrate 10 and shaped into a spiral, and a second coil 42 formed above the first coil 41 and spaced apart therefrom. The first coil 41 and the second coil 42 are connected by a connecting portion 45 at an innermost end, and are connected by another connecting portion 45 at an outermost end. The spacing between the first coil 41 and the second coil 42 realizes an inductor that has a compact size and a high Q value. Since the spiral inductor 40 is provided in the cavity 90, the spacing can be defined between the first coil 41 and the second coil 42.

Turning back to FIGS. 2A through 2C, a third chip 32 and a surface mounting component 34 are provided on the upper surface of the insulative substrate 10 by using connecting portions 35 of solder. The surface mounting component 34 may be a chip capacitor or a chip inductor.

The first chip 20 having an electrically conductive substrate is mounted on the lower surface of the insulative substrate 10 by using connecting portions 28 of solder. The first protrusion 60 is provided so as to surround the first chip 20. The first protrusion 60 has an insulative cavity wall (insulative member) 61 made of, for example, ceramics, inner interconnections 62 and first electrodes 63. The first electrodes 63 are provided on the end of the cavity wall 61, and electrically connect the passive circuit including the first chip 20 and the spiral inductor 40 to an external circuit. The second chip 30 (or the third chip that will be described later) may be electrically connected to an external circuit via the first electrodes 63 provided on the end of the first protrusion 60 in addition to the first chip 20 or the passive circuit. The first chip 20 or the passive circuit may be electrically connected to the first electrodes 64 via other components (which may, for example, be the capacitor 50 or the surface mounting component 34). The cavity wall 61 may be integrally formed with the insulative substrate 10.

In order to reduce the influence of the magnetic field generated by the spiral inductor 40, it is preferable that the first chip 20 having the substrate of a relatively high conductivity is mounted on the lower surface of the insulative substrate 10, and the second chip 30 or the third chip 32 having the substrates of less conductivity than that of the first chip 20 is mounted on the upper surface of he insulative substrate 10. The first chip 20 is mounted on the surface of the insulative substrate 10 opposite to the surface on which the spiral inductor 40 is formed, and the second chip 30 or the third chip 32 is mounted on the surface of the insulative substrate 10 on which the spiral inductor 40 is formed.

The second chip 30 is mounted above the spiral inductor 40. This makes it possible to downsize the electronic device. The second protrusion 80 is provided on the upper surface of the insulative substrate 10, so that the second chip 30 may be easily mounted above the spiral inductor 40.

The spiral inductor 40 is hermetically sealed with or covered by the second protrusion 80 and the second chip 30. For instance, in a case where a SAW (Surface Acoustic Wave) device, an FBAR (Film Bulk Acoustic Resonator) device or a MEMS (Micro Electro Mechanical Systems) device is provided, these devices are also covered hermetically. It is to be noted that the devices are required to be sealed. The spiral inductor 40 is required to be sealed because there is a spacing between the first coil 41 and the second coil 42. According to the first embodiment, all the above-described devices can be sealed at once.

The first protrusion 60 is higher than the first chip 20. Thus, even when an external mount board is flat, the electronic device of the first embodiment may easily be mounted. The second protrusion 80 is higher than the spiral inductor 40 and the capacitor 50. It is thus possible to easily mount the flat second chip 30 on the second protrusion 80.

### Second Embodiment

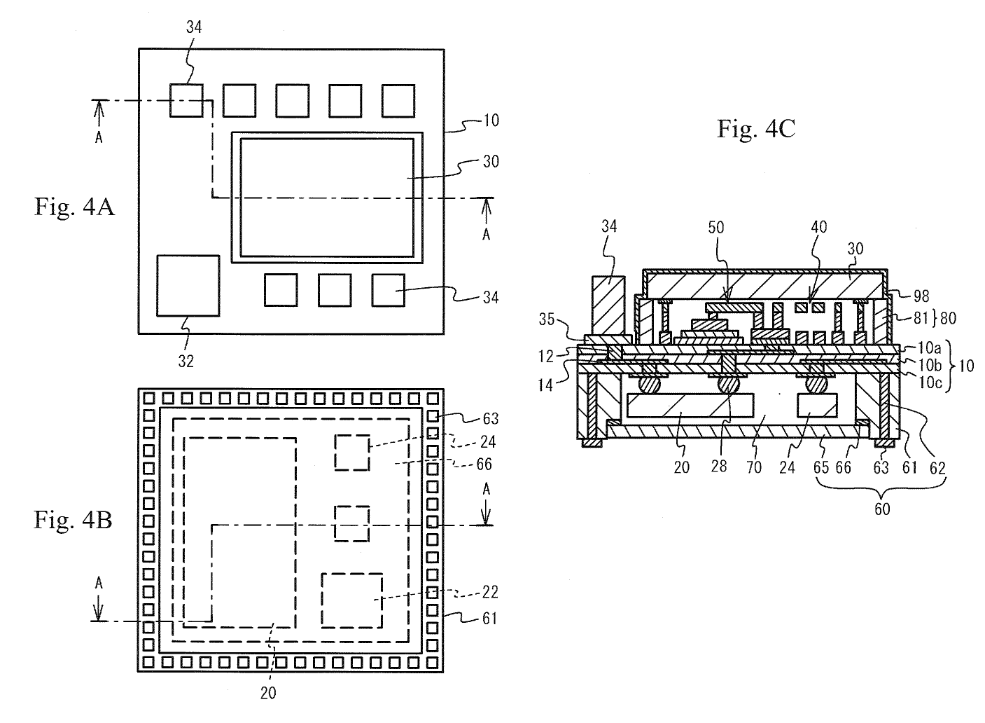

FIG. 4A is a plan view of an electronic device in accordance with a second embodiment, FIG. 4B is a bottom view thereof, and FIG. 4C is a cross-sectional view taken along a line A-A depicted in FIGS. 4A and 4B. The bottom view of FIG. 4B sees through a first lid. Referring to FIGS. 4A through 4C, the electronic device of the second embodiment has the first protrusion 60, which differs from that of the first embodiment in that the first protrusion 60 of the second embodiment has the cavity wall 61 and a first lid 65. The first lid 65 is bonded to the cavity wall 61 by a seal ring 66 made of solder or adhesive. With the above structure, a cavity 70 is hermetically sealed. The first chips 20 and 22 and surface mounting devices 24 are mounted on the lower surface of the insulative substrate 10. The other structures of the second embodiment are the same as those of the first embodiment, and a description thereof will be omitted.

According to the second embodiment, the first protrusion 60 has the first lid 65 with which the first chips 20 and 22 are hermetically sealed. Multiple first chips 20 and 22 may be mounted on the lower surface of the insulative substrate 10, and the surface mounting devices 24 may be mounted thereon.

### Third Embodiment

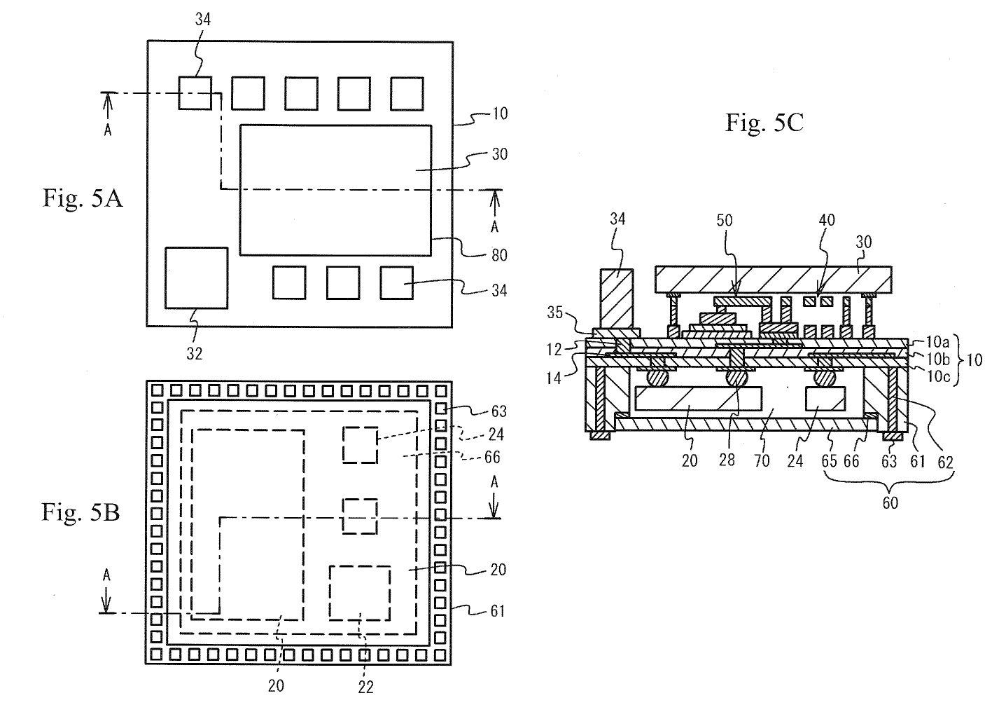

FIG. 5A is a plan view of an electronic device in accordance with a third embodiment, FIG. 5B is a bottom view thereof, and FIG. 5C is a cross-sectional view taken along a line A-A depicted in FIGS. 5A and 5B. The bottom view of FIG. 5B sees through the first lid. Referring to FIGS. 5A through 5C, the electronic device of the third embodiment differs from that of the second embodiment in that the third embodiment does not have the second protrusion 80 and the spiral inductor 40 is not sealed. The other structures of the third embodiment are the same as those of the second embodiment.

### Fourth Embodiment

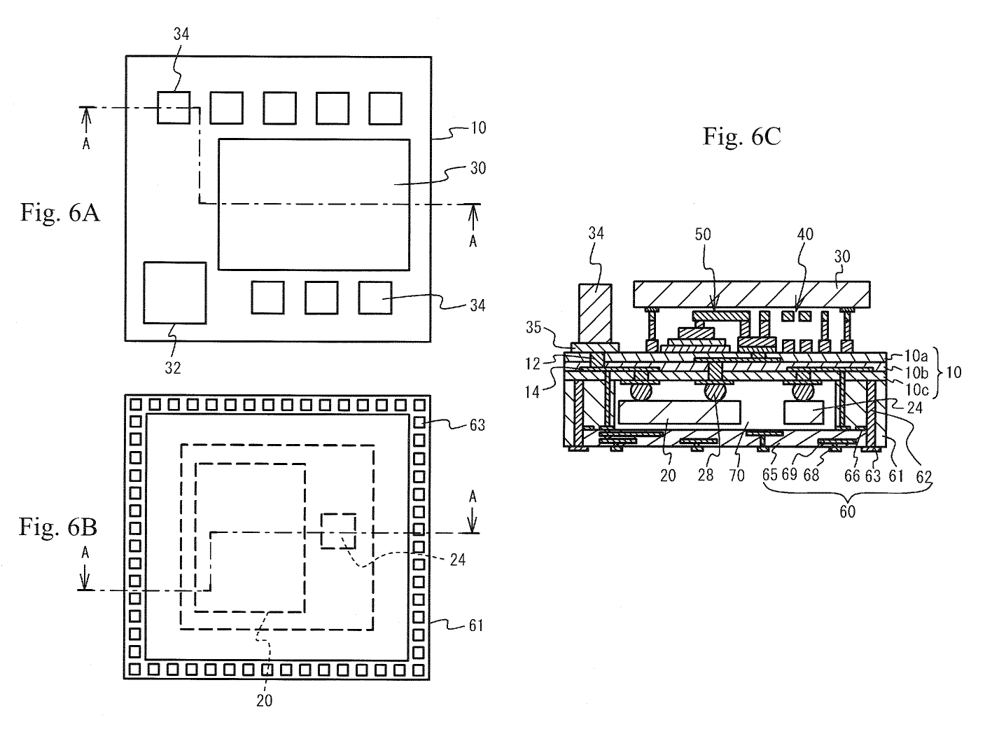

FIG. 6A is a plan view of an electronic device in accordance with a fourth embodiment, FIG. 6B is a bottom view thereof, and FIG. 6C is a cross-sectional view taken along a line A-A depicted in FIGS. 6A and 6B. The bottom view of FIG. 6B sees through the first lid. Referring to FIGS. 6A through 6C, the electronic device of the fourth embodiment differs from that of the third embodiment in that the first lid 65 of the fourth embodiment is a multilayer substrate having inner interconnections 69. In addition to the first electrodes 63 provided to the end of the cavity wall 61, first electrodes 68 are provided on an outer surface of the first lid 65. The first electrodes 68 are used to electrically connect a passive circuit that includes the first chip or the spiral inductor 40 to an external circuit. The other structures of the fourth embodiment are the same as those of the third embodiment.

According to the fourth embodiment, the first electrodes 68 are provided on the lower surface of the first lid 65, so that a large number of first electrodes 68 can be provided like a ball grid array.

### Fifth Embodiment

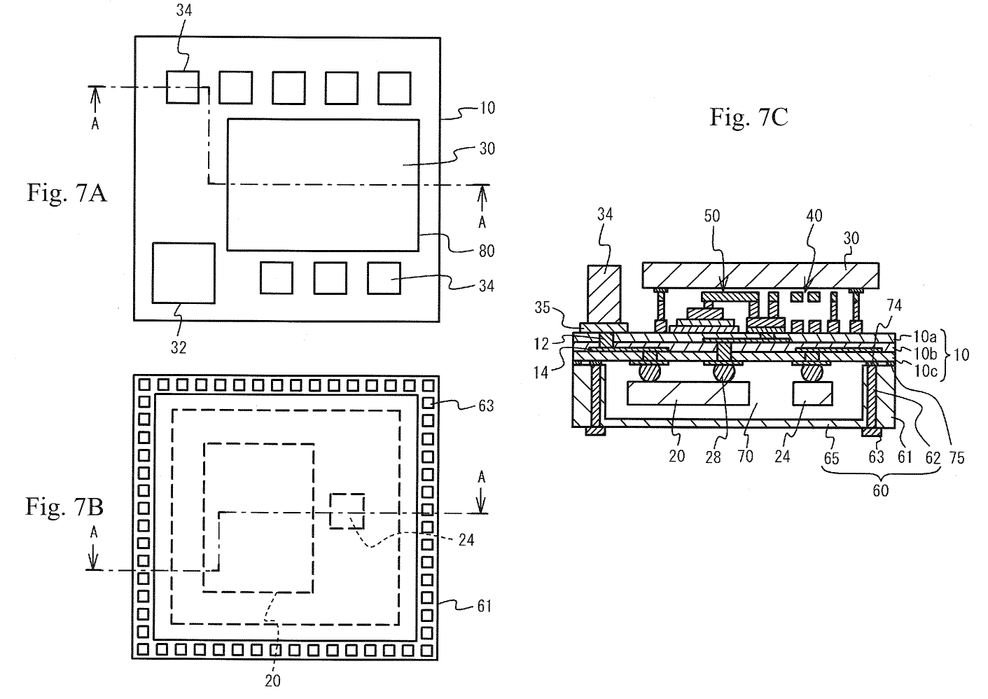

FIG. 7A is a plan view of an electronic device in accordance with a fifth embodiment, FIG. 7B is a bottom view thereof, and FIG. 7C is a cross-sectional view taken along a line A-A depicted in FIGS. 7A and 7B. The bottom view of FIG. 7B sees through the first lid. Referring to FIGS. 7A through 7C, the electronic device of the fifth embodiment differs from that of the fourth embodiment in that the fourth embodiment in that the insulative cavity wall 61 made of, for example, ceramics and the first lid 65 are integrally formed. The first protrusion 60 is spaced apart from the insulative substrate 10 and is connected to the insulative substrate 10 by a seal ring 75 made of solder, adhesive or the like and connecting portions 74 of solder or the like for electrically connecting the inner interconnections 14 of the insulative substrate 10 and the inner interconnections 62 of the first protrusion 60. The other structures of the fifth embodiment are the same as those of the third embodiment.

According to the fifth embodiment, the first protrusion 60 is spaced apart from the insulative substrate 10 and is connected thereto by the connecting portions 74 and the seal ring 75. Thus, the pad electrodes 16 on the surface of the insulative substrate 10 may be formed by printing, so that the fabrication process can be simplified.

### Sixth Embodiment

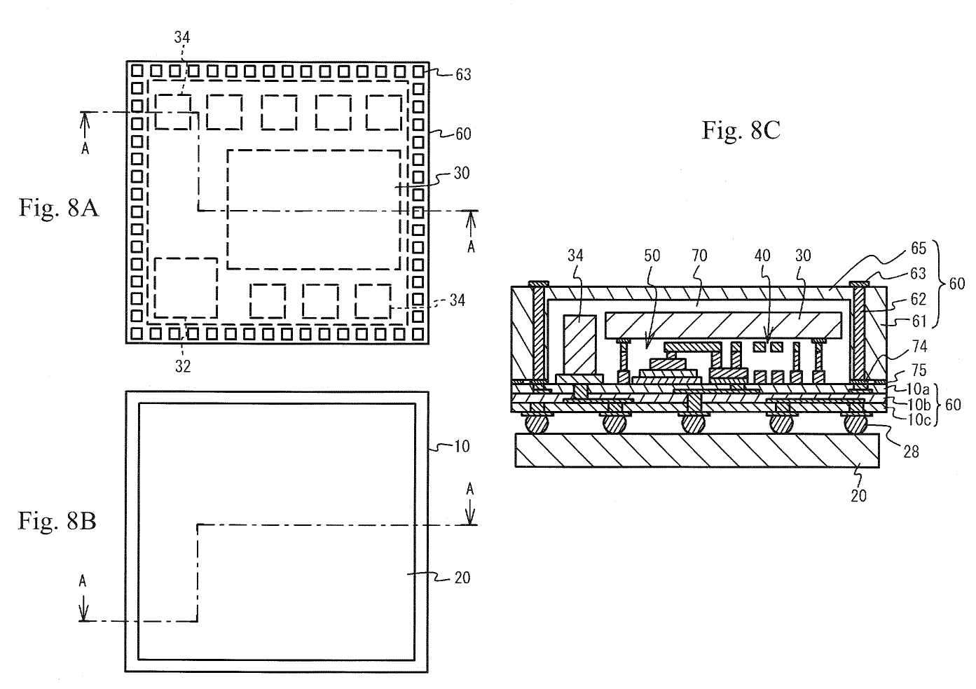

A sixth embodiment has an arrangement in which the first protrusion 60 is provided on the upper surface of the insulative substrate 10. FIG. 8A is a plan view of an electronic device in accordance with the sixth embodiment, FIG. 8B is a bottom view thereof, and FIG. 8C is a cross-sectional view taken along a line A-A depicted in FIGS. 8A and 8B. The bottom view of FIG. 8B sees through the first lid. Referring to FIGS. 8A through 8C, the electronic device of the sixth embodiment is configured so that the first protrusion 60 is provided on the upper surface of the insulative substrate 10. The first protrusion 60 hermetically covers the second chip 30, the spiral inductor 40, the capacitor 50 and the surface mounting components 34. The first chip 20 mounted on the lower surface of the insulative substrate 10 is exposed.

### Seventh Embodiment

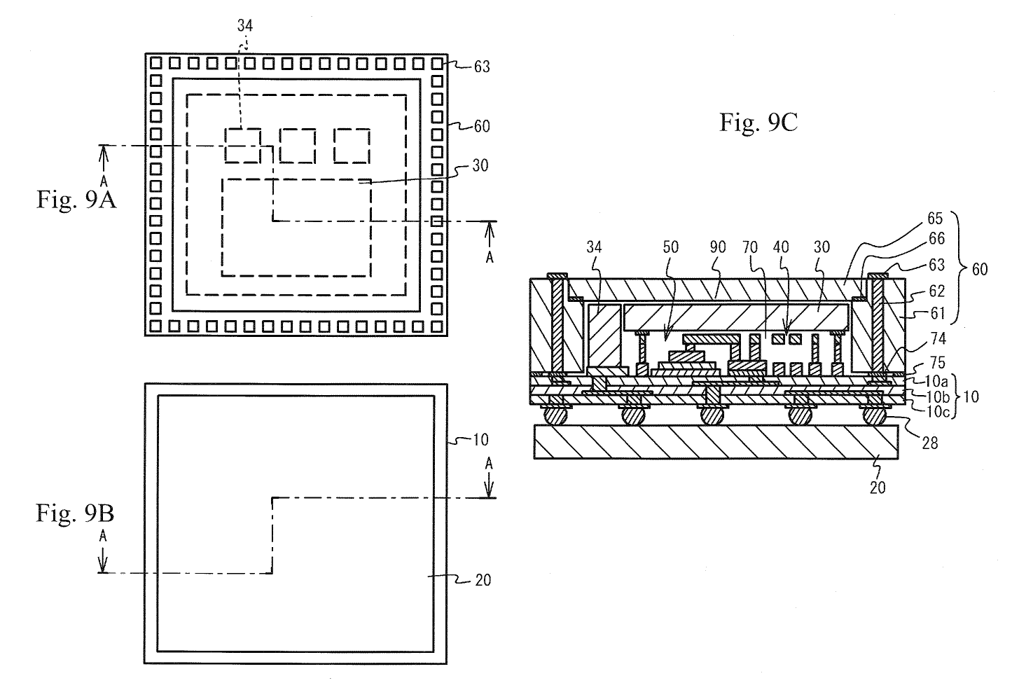

FIG. 9A is a plan view of an electronic device in accordance with a seventh embodiment, FIG. 9B is a bottom view thereof, and FIG. 9C is a cross-sectional view taken along a line A-A depicted in FIGS. 9A and 9B. The bottom view of FIG. 9B sees through the first lid. Referring to FIGS. 9A through 9C, the electronic device of the seventh embodiment differs from that of the sixth embodiment in that the first protrusion 60 has a structure similar to that of the second embodiment in which the cavity wall 61 and the first lid 65 are separated from each other and are bonded by a seal ring 66. The other structures of the seventh embodiment are the same as those of the sixth embodiment.

### Eighth Embodiment

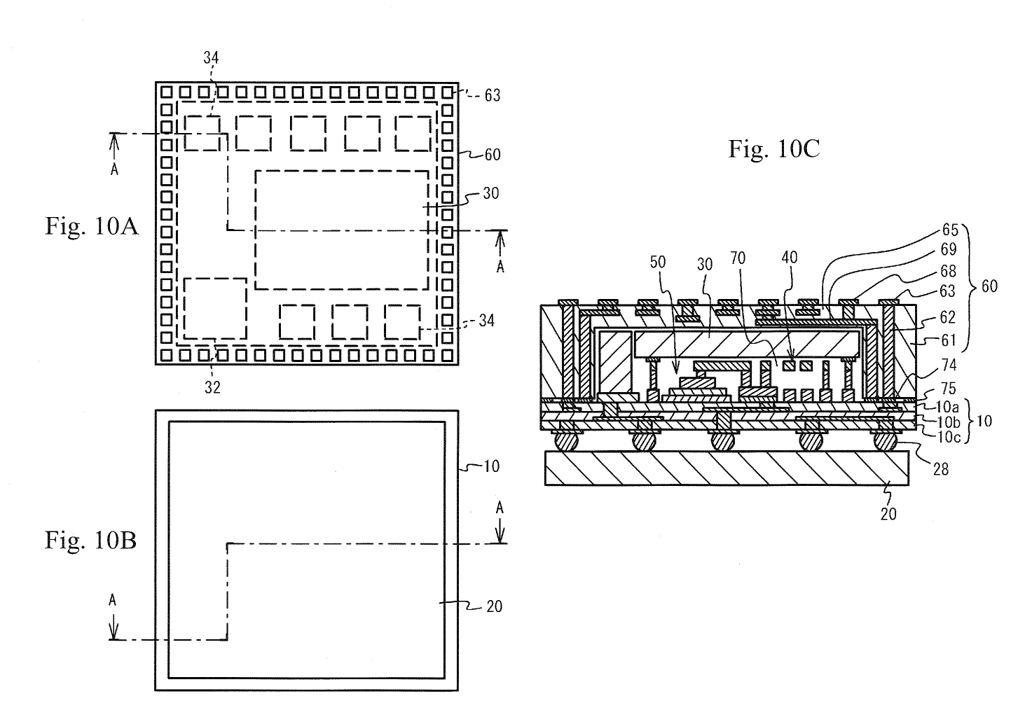

FIG. 10A is a plan view of an electronic device in accordance with an eighth embodiment, FIG. 10B is a bottom view thereof, and FIG. 10C is a cross-sectional view taken along a line A-A depicted in FIGS. 10A and 10B. The bottom view of FIG. 10B sees through the first lid. Referring to FIGS. 10A through 10C, the electronic device of the eighth embodiment differs from that of the sixth embodiment in which the cavity wall 61 and the first lid 65 of the first protrusion 60 are integrally formed and the first lid 65 has inner interconnections 69. Further, the first electrodes 68 are formed on the upper surface of the first lid 65. The other structures of the eighth embodiment are the same as those of the sixth embodiment.

### Ninth Embodiment

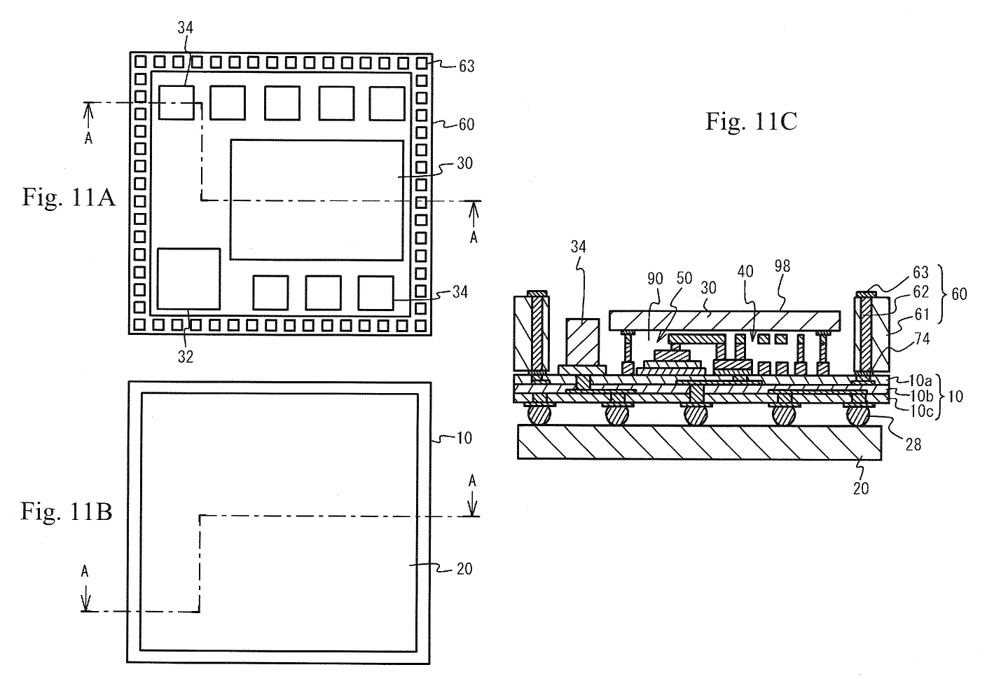

FIG. 11A is a plan view of an electronic device in accordance with a ninth embodiment, FIG. 11B is a bottom view thereof, and FIG. 11C is a cross-sectional view taken along a line A-A depicted in FIGS. 11A and 11B. The bottom view of FIG. 11B sees through the first lid. Referring to FIGS. 11A through 11C, the electronic device of the ninth embodiment differs from that of the sixth embodiment in which the first protrusion 60 does not have the first lid. The other structures of the ninth embodiment are the same as those of the sixth embodiment.

### Tenth Embodiment

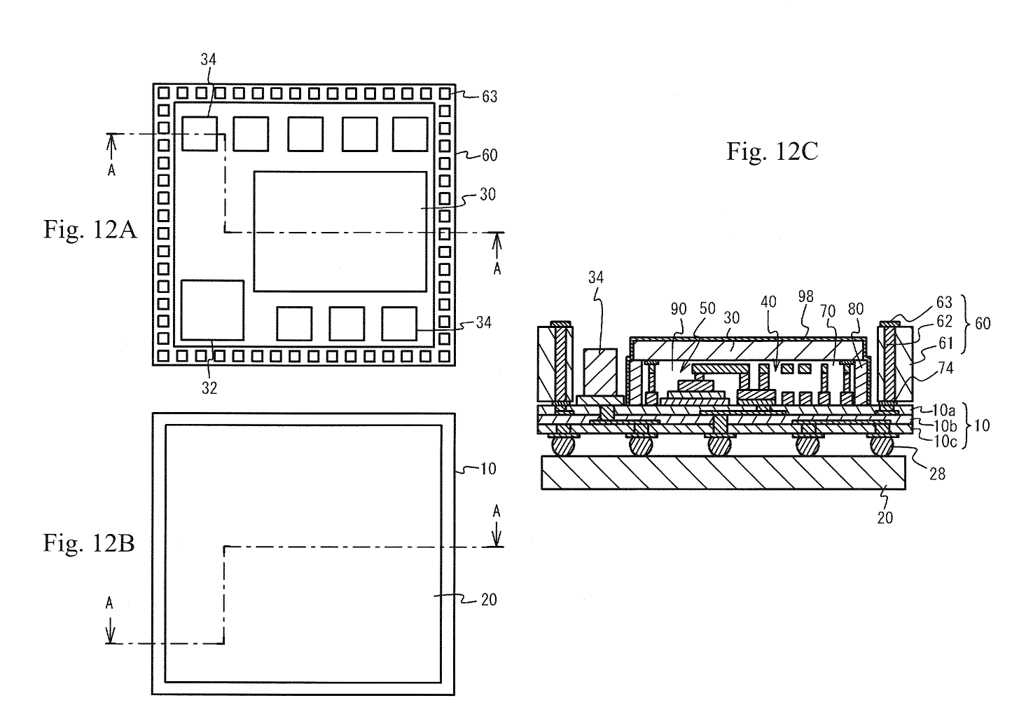

FIG. 12A is a plan view of an electronic device in accordance with a tenth embodiment, FIG. 12B is a bottom view thereof, and FIG. 12C is a cross-sectional view taken along a line A-A depicted in FIGS. 12A and 12B. Referring to FIGS. 12A through 12C, the electronic device of the tenth embodiment differs from that of the ninth embodiment in that the second chip 30 is mounted on the first protrusion 60. Further, the electronic device has the second protrusion 80 and the seal member 98 for covering the second chip 30. Thus, the spiral inductor 40 and the capacitor 50 are sealed as in the case of the first embodiment. The other structures of the tenth embodiment are the same as those of the ninth embodiment.

### Eleventh Embodiment

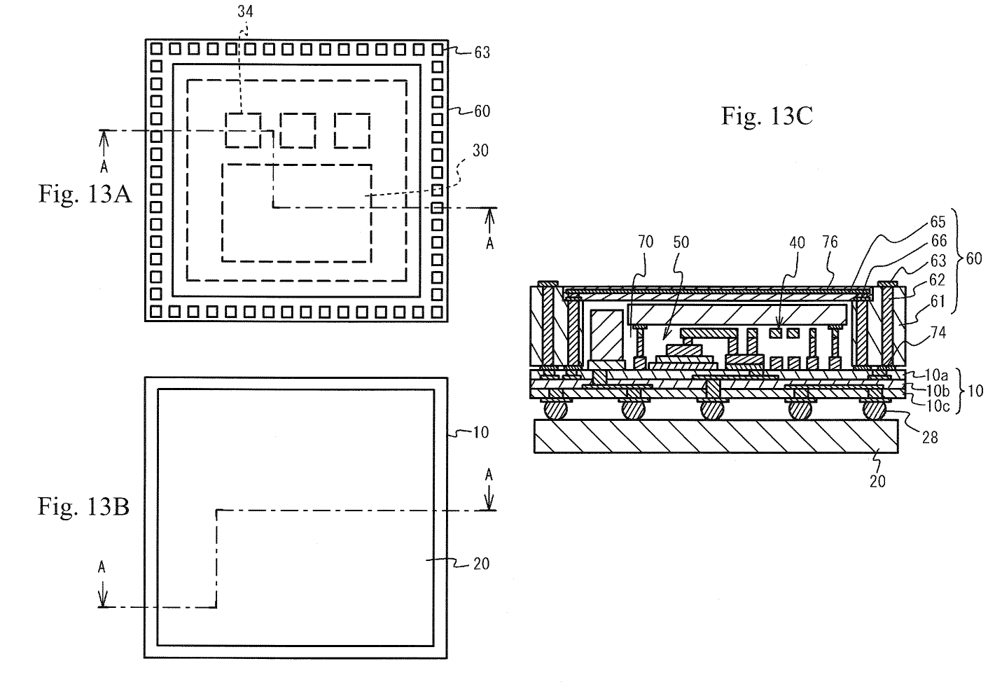

FIG. 13A is a plan view of an electronic device in accordance with an eleventh embodiment, FIG. 13B is a bottom view thereof, and FIG. 13C is a cross-sectional view taken along a line A-A depicted in FIGS. 13A and 13B. Referring to FIGS. 13A through 13C, the electronic device of the eleventh embodiment differs from that of the seventh embodiment in that a shield electrode 76 made of a metal is formed within the first lid 65 that is insulative. The shield electrode prevents the magnetic field of the spiral inductor 40 from affecting an external circuit or element.

### Twelfth Embodiment

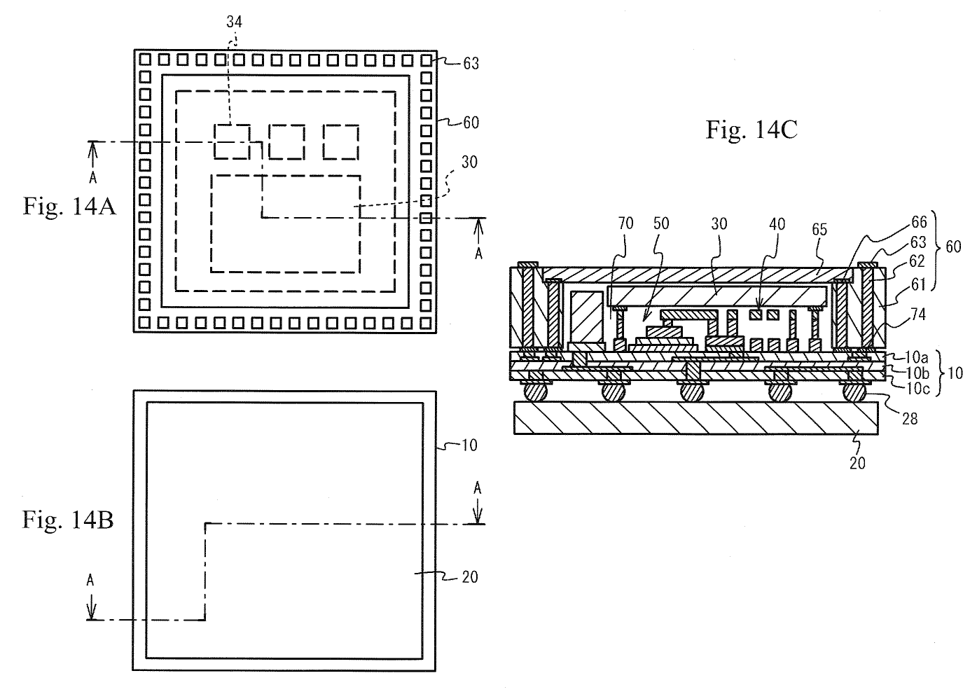

FIG. 14A is a plan view of an electronic device in accordance with a twelfth embodiment, FIG. 14B is a bottom view thereof, and FIG. 14C is a cross-sectional view taken along a line A-A depicted in FIGS. 14A and 14B. Referring to FIGS. 14A through 14C, the electronic device of the twelfth embodiment differs from that of the eleventh embodiment in that the first lid 65 is made of a metal. The first lid 65 functions as a shield electrode. It is thus possible to prevent the magnetic field of the spiral inductor 40 from affecting an external circuit or element.

### Thirteenth Embodiment

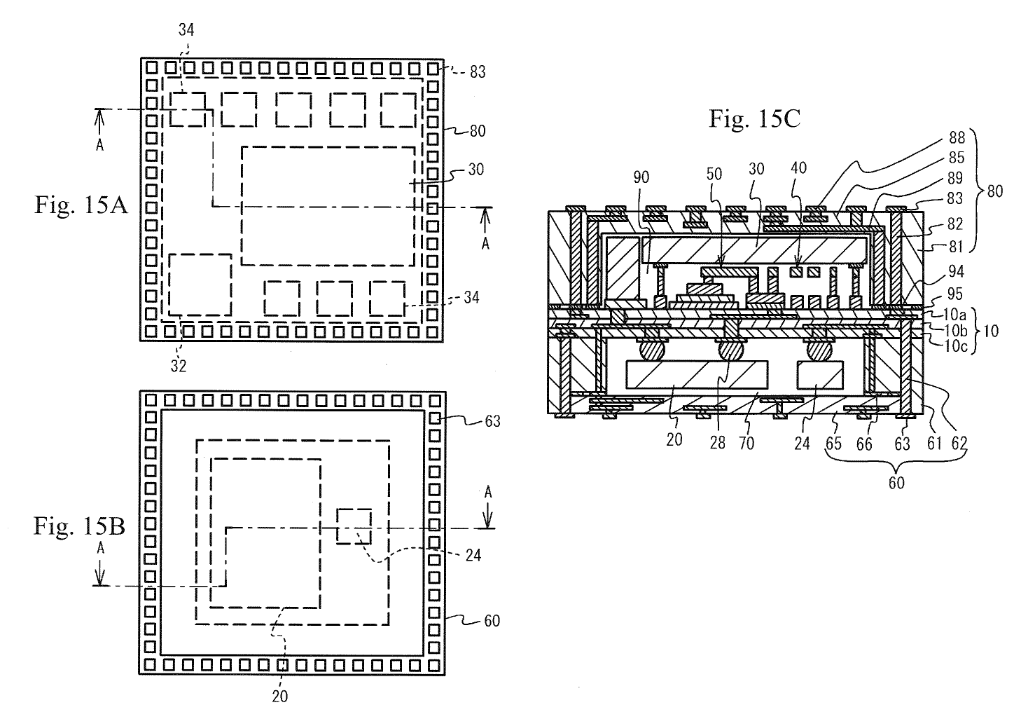

An electronic device of a thirteenth embodiment has an arrangement in which the first protrusion 60 is provided on the lower surface of the insulative substrate 10 and the second protrusion 80 is provided on the upper surface of the insulating substrate 10. FIG. 15A is a plan view of the electronic device in accordance with the thirteenth embodiment, FIG. 15B is a bottom view thereof, and FIG. 15C is a cross-sectional view taken along a line A-A depicted in FIGS. 15A and 15B. Referring to FIGS. 15A through 15C, the electronic device of the thirteenth embodiment differs from that of the fourth embodiment in that the second protrusion 80 is provided on the insulative substrate 10. The second protrusion 80 is configured so that a cavity wall 81 and a second lid 85 are integrally formed by an insulative member such as ceramics. Inner interconnections 82 and 89 are respectively provided in the cavity wall 81 and the second lid 85. Second electrodes 88 are provided on an outer surface of the second lid 85. The second electrodes 88 are used to electrically connect the passive circuit including the spiral inductor 40 and the first chip 20 or the second chip 30 to an external device or circuit. The second protrusion 80 is bonded to the insulative substrate 10 by a seal ring 95, which maybe made of solder or adhesive. Connecting portions 94, which may be made of solder, are used to connect the inner interconnections 14 of the insulative substrate 10 and the inner interconnections 82 within the cavity wall 81. The other structures of the thirteenth embodiments are the same as those of the fourth embodiment.

According to the thirteenth embodiment, the second protrusion 80 is provided on the upper surface of the insulative substrate 10 (opposite to the surface thereof on which the first protrusion 60 is provided). The second protrusion 80 has the second lid 85, which is commonly provided to the spiral inductor 40 and the second chip 30 in order to realize hermetical healing.

### Fourteenth Embodiment

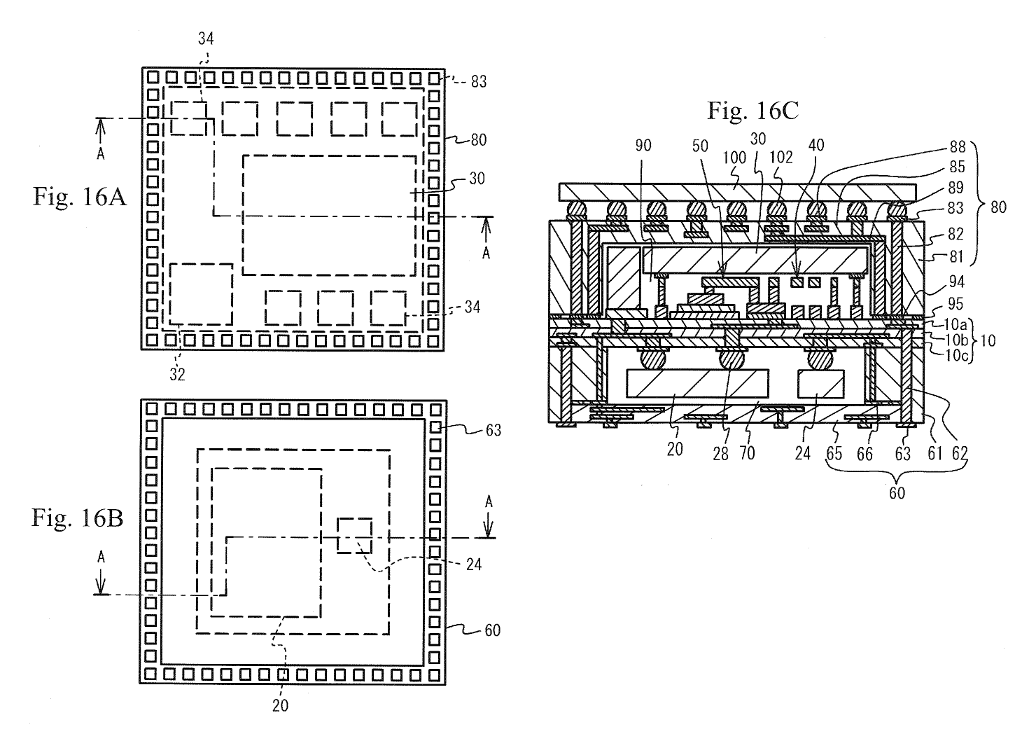

FIG. 16A is a plan view of an electronic device in accordance with a fourteenth embodiment, FIG. 16B is a bottom view thereof, and FIG. 16C is a cross-sectional view taken along a line A-A depicted in FIGS. 16A and 16B. Referring to FIGS. 16A through 16C, an electronic device of the fourteenth embodiment differs from that of the thirteenth embodiment in that the third chip 100 is mounted on the second electrodes 83 and 88 of the second protrusion 80 via bumps 102 of solder or the like. The other structures of the fourteenth embodiment are the same as those of the thirteenth embodiment.

According to the fourteenth embodiment, the third chip 100 is mounted on the outer surface of the second lid 85, so that the mounting density can be increased.

### Fifteenth Embodiment

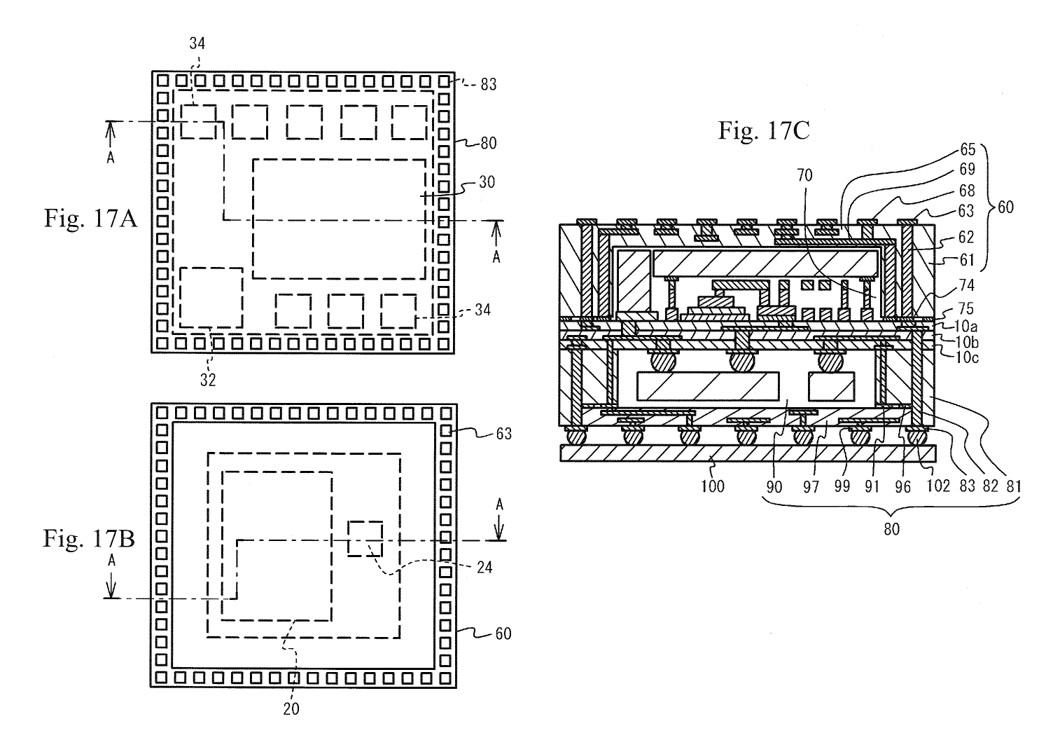

A fifteenth embodiment has an arrangement in which the first protrusion 60 is provided on the upper surface of the insulative substrate 10, and the second protrusion 80 is mounted on the lower surface of the insulative substrate 10. FIG. 17A is a plan view of the electronic device in accordance with a fifteenth embodiment, FIG. 17B is a bottom view thereof, and FIG. 17C is a cross-sectional view taken along a line A-A depicted in FIGS. 17A and 17B. Referring to FIGS. 17A through 17C, the electronic device of the fifteenth embodiment differs from the eighth embodiment in that the second protrusion 80 is provided on the lower surface of the insulative substrate 10. The second protrusion 80 is the same as the first protrusion 60 of the fourth embodiment. The third chip 100 is mounted on the second electrodes 83 and 88 via bumps 102 of solder or the like. The other structures of the fifteenth embodiment are the same as those of the eighth embodiment.

According to the fifteenth embodiment, the first protrusion 60 is provided on the upper surface of the insulative substrate 10, and the second protrusion 80 is provided on the lower surface of the insulative substrate 10.

### Sixteenth Embodiment

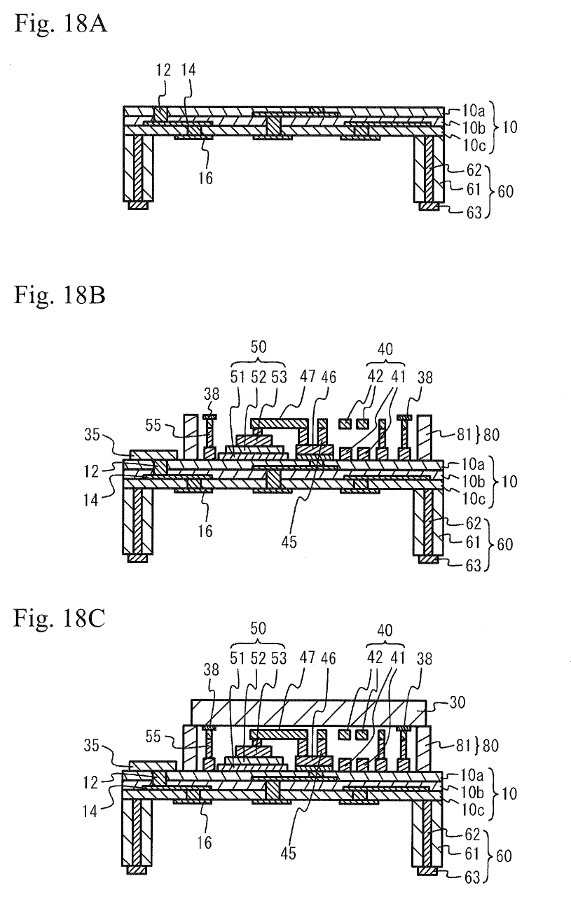

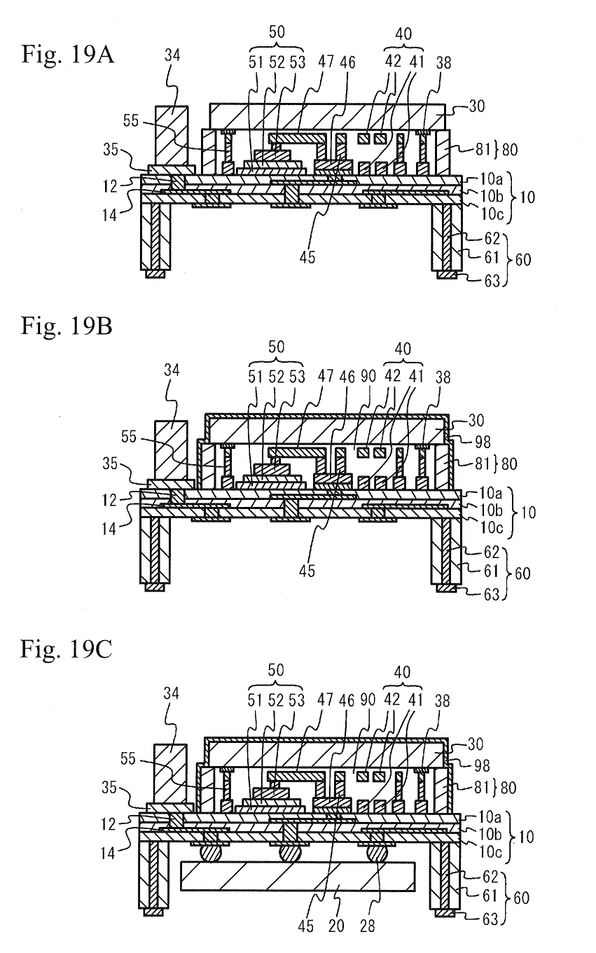

A sixteenth embodiment is a method of fabricating the electronic device of the first embodiment. FIGS. 18A through 19C are respectively cross-sectional views that illustrates the method of fabricating the electronic device. Referring to FIG. 18A, an LTCC wafer having the insulative substrate 10 integrally formed with the first protrusion 60 is produced. Referring to FIG. 18B, the spiral inductor 40, the capacitor 50 and the connecting portions 55 are formed on the insulative substrate 10. The spiral inductor 40 and the capacitor 50 may be produced by, for example, a method as described in Document 3 or 4. The connecting portions 35 made of, for example, solder, are formed on the insulative substrate 10 in order to mount the second protrusion 80 made of ceramics and the surface mounting components. Referring to FIG. 18C, the second chip 30, which may be a SAW device, is flip-chip mounted on the connecting portions 55 and the second protrusion 80. Photosensitive epoxy region (not illustrated) is coated so as to cover the second protrusion 80 and the second chip 30. Then, the photosensitive epoxy resin is annealed at a temperature of 180° C. to 200° C. and is thus cured.

Referring to FIG. 19A, the surface mounting component 34 is mounted on the upper surface of the insulative substrate 10 by using the connecting portions 35. Referring to FIG. 19B, a coating film of SOG (Spin on Glass) is provided by coating and is cured by annealing at, for example, 200° C. In FIG. 19B, the photosensitive epoxy region and the coating film are integrally illustrated as a seal member 98. The coating film prevents water from passing through the photosensitive epoxy resin. The first chip 20 is flip-chip mounted on the lower surface of the insulative substrate 10 by using the pad electrodes 16 functioning as the connecting portions.

### Seventeenth Embodiment

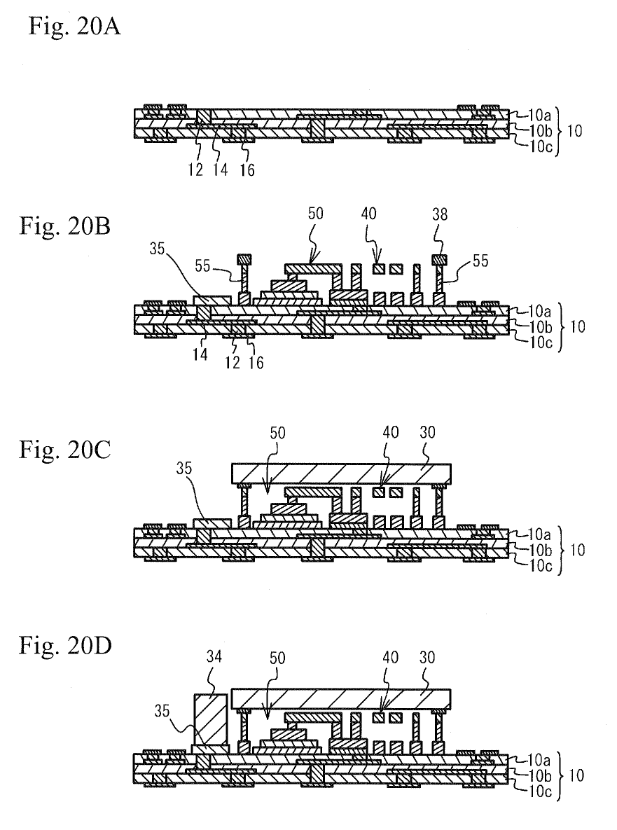

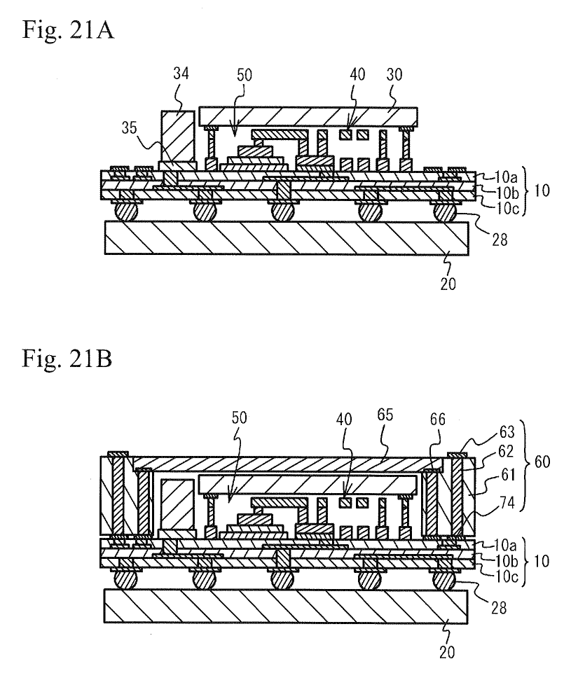

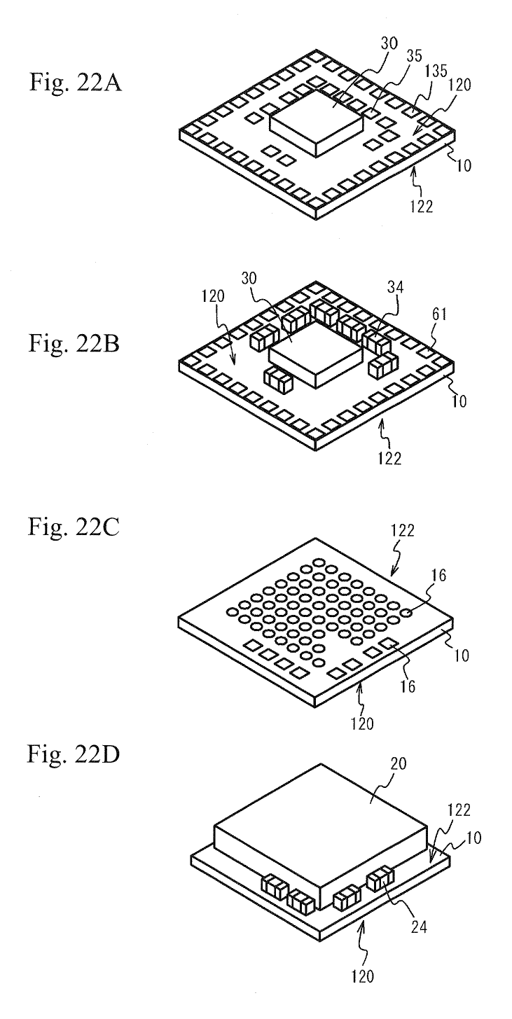

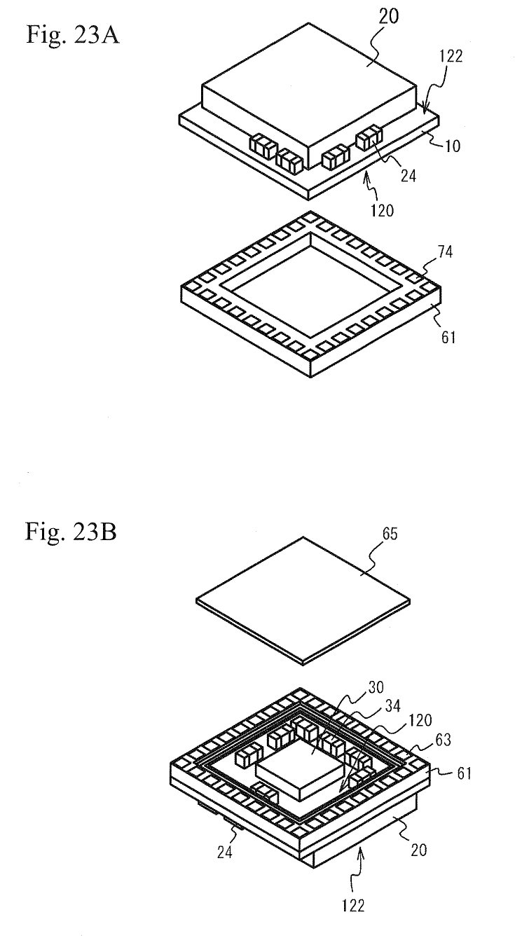

A seventeenth embodiment is a method of fabricating the electronic device of the twelfth embodiment. FIGS. 20A through 21B are cross-sectional views that illustrate the method of fabricating the electronic device. FIGS. 22A, 22B and 23B are respectively perspective views of the electronic device from an upper surface 120 of the insulative substrate 10, and FIGS. 22C, 22D and 23A are respectively perspective view thereof from a lower surface 122. Referring to FIG. 20A, the insulative substrate 10 formed by a ceramic multilayer substrate is produced. Referring to FIG. 20B, the connecting portions 35 made of solder are formed on the upper surface 120 of the insulative substrate 10 by printing. The spiral inductor 40, the capacitor 50 and the connecting portions 55 are formed by, for example, a method as described in Document 3 or 4. Referring to FIGS. 20C and 22A, the second chip 30 is flip-chip mounted on the connecting portions 55. Referring to FIGS. 20D and 22B, the surface mounting component 34 is mounted on the connecting portions 35.

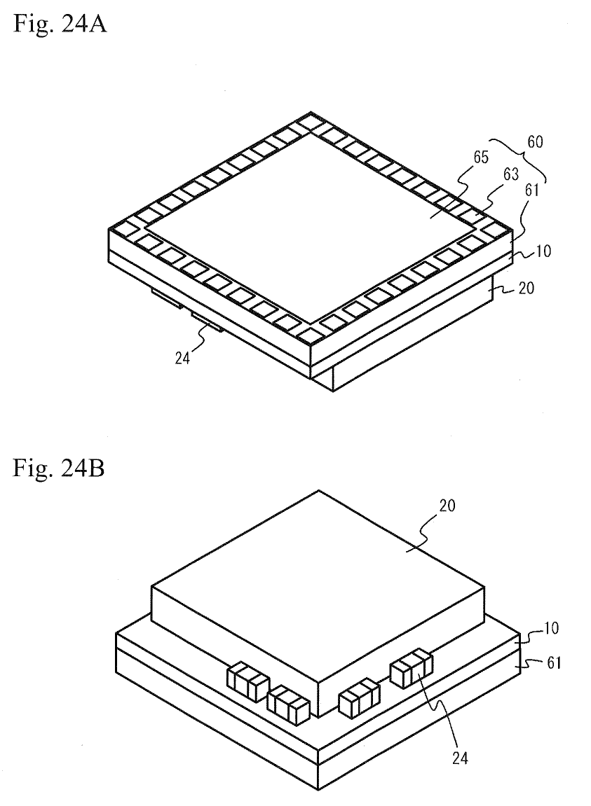

FIG. 22C illustrates the lower surface 122 of the insulative substrate 10. Referring to FIGS. 21A and 22D, the first chip 20 and the surface mounting devices 24 are flip-chip mounted on the lower surface 122 of the insulative substrate 10 by using the connecting portions 28 of solder or the like. Referring to FIG. 23A, the cavity wall 61 of the first protrusion 60 is formed on the upper surface 120 of the insulative substrate 10 by using the connecting portions 74 of solder or the like. Referring to FIGS. 21B and 23B, the first lid 65 made of a metal like stainless is mounted on the cavity wall 61. Thus, the electronic device is completed. FIG. 24A is a perspective view of the completed electronic device from the upper side thereof.

According to the seventeenth embodiment, the insulative substrate 10 and the cavity wall 61 of the first protrusion 60 are formed by the separate ceramic substrates, and are connected by solder. It is thus possible to use the printing method to form the connecting portions 35 illustrated in FIGS. 20B and 22A.

The first through seventeenth embodiments employ the ceramic multilayer substrate for the insulative substrate 10. Preferably, the insulative substrate 10 is formed from a ceramic substrate like HTCC or LTCC formed into a wafer. The insulative substrate 10 thus formed has a satisfactory mechanical strength. In FIG. 20B related to the seventeenth embodiment, the spiral inductor 40 and the capacitor 50 may be produced by the semiconductor process. The insulating substrate 10 may be a glass substrate having through electrodes or a semiconductor wafer having high resistance. The insulative substrate 10 may be a substrate made of resin or a printed-circuit board. It is to be noted that the dielectric layer 52 (see FIG. 2C) of the capacitor 50 is formed at a temperature as high as 300° C. or higher. It is thus preferable that the insulative substrate 10 is made of ceramics, semiconductor or glass having high thermal resistance.

The first protrusion 60 and the second protrusion 80 are preferably formed by ceramic substrates such as HTCC or LTCC formed into a wafer. A resin substrate having inner interconnections may be used. The first and second lids are preferably formed by ceramic substrates such as HTCC or LTCC formed into a wafer. Thus, multilayer inner interconnections can be formed in the first lid 65 and the second lid 85 as in the case of the fourth, eight, thirteenth, fourteenth or fifteenth embodiments. The first electrodes 68 and the second electrodes 88 may be provided on the outer surface of the first lid 65 and that of the second lid 85. The first electrodes 68 and the second electrodes 88 may be arranged in a grid, so that many first electrodes 68 and second electrodes 88 can be provided.

The first protrusion 60 and the second protrusion 80 may divide the upper and lower surfaces of the insulative substrate 10 into multiple sections. In this case, each of the sections has the respective cavity.

In the insulative substrate 10 or the first lid 65 and the second lid 85 having the multilayer interconnections, the inner interconnections 14, 69 and 89 may be used to form part or all of a resistor, capacitor, inductor, distribution constant line (microstrip or coupler), distribution constant resonator, lump parameter filter and/or distribution constant filer. An active element such as an IC chip may be built in the insulative substrate 10, the field lid 65 and/or the second lid 85.

Other than the spiral inductor 40 and the capacitor 50, the passive element provided on the insulative substrate 10 may be part or all of a resistor, distribution constant line (microstrip or coupler), distribution constant resonator, lump parameter filter and/or distribution constant filer.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. An electronic device comprising:
an insulative substrate;
a spiral inductor formed by an interconnection layer provided on a first surface of the insulative layer;
a first chip that is mounted on a second surface of the insulative layer opposite to the first surface and is electrically connected to a passive circuit including the spiral inductor, the first chip having an electrically conductive substrate; and
a first protrusion that is provided on one of the first and second surface of the insulative substrate and protrudes therefrom, the first protrusion being electrically connected to one of the passive circuit and the first chip to an external circuit.

2. The electronic device as claimed in claim 1, further comprising a second chip provided on the first surface of the insulative substrate.

3. The electronic device as claimed in claim 2, wherein the second chip has a substrate having a conductivity lower than that of the electrically conductive substrate of the first chip.

4. The electronic device as claimed in claim 2, wherein the second chip is provided above the spiral inductor.

5. The electronic device as claimed in claim 1, wherein the spiral inductor includes a first coil of a spiral shape provided on the insulative substrate, and a second coil of a spiral shape spaced apart from and located above the first coil.

6. The electronic device as claimed in claim 1, wherein the first protrusion includes an insulative member and first electrodes that are provided on an end of the insulative member and is electrically connected to the one of the passive circuit and the first chip.

7. The electronic device as claimed in claim 6, wherein the insulative member is integrally formed with the insulative substrate.

8. The electronic device as claimed in claim 6, wherein the first protrusion is spaced apart from the insulative substrate and is connected thereto by connecting portions.

9. The electronic device as claimed in claim 1, wherein the first protrusion includes a first lid that hermetically covers the first chip and/or the spiral inductor.

10. The electronic device as claimed in claim 9, wherein the first protrusion includes first electrodes that are provided on an outer surface of the first lid and electrically connect the one of the passive circuit and the first chip to the external circuit.

11. The electronic device as claimed in claim 9, wherein the first lid includes a shield electrode.

12. The electronic device as claimed in claim 2, further comprising a second lid that is provided on the first surface of the insulative substrate and mounts the second chip above the spiral inductor.

13. The electronic device as claimed in claim 12, wherein the second protrusion and the second chip hermetically cover the spiral inductor.

14. The electronic device as claimed in claim 13, wherein a SAW device, an FBAR device or a MEMS device is formed on a surface of the second chip that faces the upper surface of the insulative substrate.

15. The electronic device as claimed in claim 1, further comprising a second protrusion that is provided on the other one of the first and second surface of the insulative substrate and hermetically covers the first chip and/or the spiral inductor.

16. The electronic device as claimed in claim 15, further comprising a third chip mounted on an outer surface of the second lid.

17. The electronic device as claimed in claim 15, wherein the second protrusion is provided on the first surface of the insulative substrate, and the second lid hermetically covers the spiral inductor and the second chip provided above the spiral inductor.

18. The electronic device as claimed in claim 17, wherein the second chip includes a SAW device, an FBAR device or a MEMS device, and the spiral inductor includes a first coil of a spiral shape provided on the insulative substrate, and a second coil of a spiral shape spaced apart from and located above the first coil.

19. The electronic device as claimed in claim 1, wherein the insulative substrate is a ceramic substrate.
